(19) United States
(12) Patent Application Publication
(10) Pub. No.: US 2013/0008708 A1
(43) Pub. Date: Jan. 10, 2013

(54) ELECTRICAL SHIELDING MATERIAL COMPOSED OF METALLIZED ALUMINUM MONOFILAMENTS

(76) Inventor: Thomas F. Burke, Wayland, MA (US)

(21) Appl. No.: 13/540,944

(22) Filed: Jul. 3, 2012

Related U.S. Application Data
(60) Provisional application No. 61/505,339, filed on Jul. 7, 2011.

(51) Int. Cl. B32B 15/14; H05K 9/00

(52) U.S. Cl. 174/390; 428/605

(57) ABSTRACT

A conductive multi-fiber of aluminum/aluminum alloy monofilaments each of which has been completely and substantially uniformly coated with at least one layer of corrosion-resistant metal or metal alloy materials. The monofilaments are less than 150 microns in diameter that have been drawn separately, then bundled together and lightly twisted, for transport through a low tension electroplating process. The multi-fiber creates an RFI/EMI shielding material with low DC resistance and low weight. The metallization process includes a zincating process that prepares the monofilaments for electroplating and an electroplating process that incrementally builds up the metallized layers.

### CROSS REFERENCE TO RELATED APPLICATIONS

This application is a non-provisional application claiming priority from U.S. Provisional Application No. 61/505,339, filed Jul. 7, 2011, entitled “Electrical Shielding Material Composed of Metallized Aluminum Monofilaments.”

### STATEMENT REGARDING FEDERALLY SPONSORED RESEARCH OR DEVELOPMENT

N/A

### BACKGROUND OF THE INVENTION

The invention relates to yarns comprised of metallized aluminum monofilaments suitable for use as RFI/EMI (Radio Frequency Interference/Electromagnetic Interference) shielding materials and other electrical applications.

As the complexity and operating frequencies of electronic systems in military and commercial aerospace applications has grown, designers of the cables that interconnect system components have been obliged to meet increasingly stringent requirements for RFI/EMI protection and, because aircraft performance and operating cost are directly related to weight, demand for lighter weight cable constructions.

In conventional coaxial cable designs, internal protection against RFI/EMI is accomplished by wire mesh shields that are directly braided over the outer conductor in the cable core during the cable manufacturing process and subsequently covered with a protective polymeric jacket. Discrete cables without internal shielding are likewise protected by braided shielding which takes the form of separately-produced wire mesh tubing that fits over the cable or bundle of cables; in this case the wire mesh tubing is directly exposed to the environment which can be quite hostile in mil/aerospace applications.

Conventional RFI/EMI braided shielding materials consist of solid copper wire strands of #34 or #36 AWG wire (6.3 or 5.0 mils diameter respectively) that are typically plated with silver in coaxial cable applications (for solderability) and nickel or tin in tubing applications (for corrosion resistance). The characteristic mesh or braid pattern shown in FIG. 1 consists of “ribbons” of plated copper wires that are formed by winding multiple wire strands or “ends” (in this case 10) onto each of the bobbins that feed the braiding equipment.

RFI/EMI shielding functions by converting incident electromagnetic energy into a current that is carried to ground by the shield. Shielding effectiveness, a measure of the degree to which RFI/EMI energy is attenuated by a braided shield, is the resultant of several factors: the conductivity of the shield material; the number of braided layers; the braid angle; the “optical coverage” or degree to which the material covers the circumference of the tubing; and the gaps that appear in the braided layer.

On the strength of its excellent conductivity and low cost, plated copper wire has been the “material of choice” in braided tubing designs for many years. However, in a growing number of mil/aerospace applications, copper wire-based materials cannot satisfy the more stringent shielding requirements and weight restrictions that are specified on new cable designs. In the high frequency spectrum (100 MHz to 2.3 GHz), short wavelength EMI energy can leak through the gaps in the characteristic mesh or braid (FIG. 1) where the relatively thick ribbons of stiff copper wire intersect. When this leakage occurs, Electromagnetic Compliance (EMC) may necessitate the use of more than one layer of braid with its attendant weight and stiffness penalties.

Actually, because copper wire is much more conductive than braided shielding applications require, its very use in any airborne application carries with it an implicit weight penalty. Furthermore, even with a protective coating of electrolytic nickel or tin, copper wire has limited corrosion resistance. For example, braided tubing comprised of #36 AWG copper wire with a Class 7 coating of nickel roughly 2 microns thick can pass a standard 500 hour neutral salt spray/fog test (solution pH 6.7-7.2) but cannot pass the Navy's more demanding requirement for 200 hours exposure to a more aggressive salt spray/fog infused with sulfur dioxide (SO₂), an acidic solution (pH 2.5-3.2) that simulates aircraft carrier flight deck conditions.

The failure mechanism in this test can be traced to pinholes—inevitable in plated coatings less than about 4-5 microns in thickness—that provide the corrosive salt spray/fog solution with multiple paths to attack the underlying copper. Thicker nickel is not a desirable option as it not only adds weight but makes the tubing less flexible by stiffening the copper wires. Since heavy metal conduit must be used in lieu of braided copper wire tubing in shielding applications that call for this more demanding test, the weight penalty attributable to limited corrosion resistance is quite severe.

### DISCUSSION OF RELATED ART

U.S. Pat. No. 7,923,390 (Burke et al) describes an improved RFI/EMI shielding material in the form of a yarn comprised of ultra fine (12 or 14 micron diameter) stainless steel filaments that are completely and uniformly metallized with at least two metal or metal alloy layers. Despite the fact that the density of stainless steel (8.0 g/cm³) is nearly the same as copper (8.9 g/cm³), braided shielding constructions made with ribbons of this metallized yarn are much thinner and therefore weigh much less than their copper wire-based counterparts. In addition to imparting greater flexibility, the extremely small diameter stainless steel filaments also improve the shielding effectiveness of the braided construction by reducing the size of the gaps in the braid.

As noted above, however, shielding effectiveness is also governed in part by the conductivity of the material used to make the braid. Since stainless steel is a poor conductor, the filaments in the '390 yarn are necessarily plated with a first copper layer about 4 microns thick followed by a second layer of nickel or tin about 1 micron thick to protect the copper layer. However, from the standpoint of corrosion resistance, this metallized construction is essentially the same as a copper wire plated with a 1 micron thick layer of nickel or tin. Consequently, while braided tubing made with this stainless steel yarn can pass a 500 hour neutral salt spray/fog test, it cannot pass a more aggressive 200 hour test involving salt spray/fog infused with sulfur dioxide. Thus, despite its merits with respect to weight reduction, flexibility, and shielding effectiveness, the metallized yarn of the '390 patent does not provide a complete solution for the full range of braided shielding applications.

With much better conductivity and a density roughly one-third that of stainless steel, aluminum wire would seem to be a promising candidate for further weight reduction in braided shielding applications. However, because aluminum is extremely vulnerable to corrosion, it has not been successfully applied to exposed RFI/EMI shielding applications as a substitute for braided copper/nickel or copper/tin wire.

In U.S. Pat. No. 5,414,211 Chan proposes the use of “iridite” chromate-coated #36 AWG (5 mils or 0.125 mm diameter) aluminum wire in lieu of #36 AWG tin-plated copper wire for exposed braided RFI/EMI shielding. Chan's data indicates that this approach reduced the weight of braided shielding in various cable constructions by as much as 67% (which is consistent with a one-to-one substitution of aluminum wire for copper-tin wire). Chan also reported that his iridite-coated aluminum braid survived a 136 hour neutral salt spray test, but prospective users in the mil/aero community discovered that it could not pass the accepted 500 hour threshold for this test, not to mention the more aggressive 200 hour test. This deficiency was found to arise from the fact that the Angstrom-thick iridite coating was easily abraded in the braiding process and in subsequent handling.

In U.S. Pat. No. 3,795,760 Raw et al propose a composite copper-aluminum wire for use as a braided shielding material incorporated into a television distribution cable. The composite wire is formed by first cladding an aluminum rod with a jacketing layer of copper, then drawing the rod down to a diameter corresponding to 0.15 mm (6.3 mils) diameter. However, corrosion of the bare copper surfaces of the braided shield is not an issue in this application because they are protected by sheaths of polyvinyl chloride.

In U.S. Pat. No. 5,965,279 Yu proposes the plating of individual aluminum wires as small as 0.102 mm (4 mils) in diameter with copper and tin for use in a braided shield but the wires in this case are also protected from corrosion by virtue of being encapsulated within a coaxial cable.

The prior art also contains numerous examples of larger diameter wires similarly made by cladding or plating aluminum cores with copper and nickel/tin. However, these composites, which are too thick and heavy to use in braided shielding applications, are invariably proposed for use as current-carrying conductors protected individually by polymeric coatings or, in a conventional stranded cable construction, grouped together within a protective polymeric jacket.

In U.S. Pat. No. 7,105,740, for example, Allaire et al. propose an aluminum rod pre-plated with a layer of copper and a layer of nickel as the feedstock material for a wire drawing process capable of producing wires as small as 0.200 mm (8 mils) in diameter. In this case the nickel coating, which is about 2 microns thick after the wire is drawn, is reported to have sufficient continuity to resist immersion in a polysulfide bath for at least 30 seconds without visible traces of attack of the underlying copper. However, this test, which is routinely specified for conductors that will eventually be protected with polymeric coatings, is not nearly as stringent as the above-mentioned salt spray/fog tests, with or without the addition of sulfur dioxide.

Thus, despite its otherwise desirable weight and conductivity properties, the metallized (clad or plated) aluminum wire of the prior art has not found use in exposed braided RFI/EMI shielding applications due to its lack of robust corrosion resistance.

### BRIEF SUMMARY OF THE INVENTION

The present invention provides a multi-filament yarn or multi-fiber comprised of a plurality of ultra-fine aluminum/aluminum alloy monofilaments each of which has been completely and substantially uniformly coated with at least one layer of corrosion-resistant metal or metal alloy materials. The aluminum yarn is comprised of aluminum/aluminum alloy monofilaments less than 150 microns in diameter that have been drawn separately, then bundled together and lightly twisted to form a yarn suitable for transport through a low tension electroplating process.

The metallized aluminum monofilaments provide a yarn that is not only lighter but more conductive than stainless steel yarn and is thus ideally suited to the goal of achieving an RFI/EMI shielding material with low DC resistance and low weight.

The metallization process consists of two parts, a zincating process that prepares the surfaces of the aluminum monofilaments for electroplating, and an electroplating process comprised of a series of plating stations, each having small plating cells that incrementally build up the metallized layers. Although pinholes or plating defects can randomly form in any one of these cells, the transport of the yarn through the multiplicity of cells creates a multilayer structure that serves to minimize the likelihood that corrosive fluid will find a path from an outer surface of the metallized monofilaments to the aluminum monofilament even with a single metal/metal alloy coating.

For applications requiring more robust corrosion resistance and/or greater conductivity, the electroplating process can be configured to sequentially deposit different metal/metal alloy coatings. For best corrosion resistance, this capability can be used to construct a “first line of defense” wherein the outer two layers are comprised of a noble metal/metal alloy and a less noble metal/metal alloy that form a corrosion-retarding galvanic couple in the presence of an electrolytic fluid such as salt spray/fog. In one embodiment, for example, the outermost coating is a layer of nickel or nickel alloy that, by virtue of being less noble than the immediately underlying layer of silver/silver alloy, becomes the “sacrificial anode” of the galvanic couple. Thus, the metallized aluminum yarn of the present invention can be readily adapted to address the wide range of corrosion conditions found in exposed RFI/EMI braided shielding applications.

### BRIEF DESCRIPTION OF THE SEVERAL VIEWS OF THE DRAWINGS

The invention will be more fully described in the following detailed description taken in conjunction with the accompanying drawings, wherein:

FIG. 1 shows a braided tubing pattern (flattened) showing ribbons of conventional nickel-plated copper wires;

FIG. 2 is a sectional illustration of the multilayer structure produced in the electroplating process stations;

FIG. 3 is a generalized schematic block diagram of the steps involved in the aluminum/aluminum alloy yarn metallization process;

FIG. 4 is a schematic block diagram of the steps involved in the yarn metallization process in accordance with one embodiment of the present invention;

FIG. 5 is a schematic block diagram of the steps involved in the yarn metallization process in accordance with one embodiment of the present invention;

FIG. 6 is a schematic block diagram of the steps involved in the yarn metallization process in accordance with one embodiment of the present invention; and

FIG. 7 is a schematic block diagram of the steps involved in the yarn metallization process in accordance with one embodiment of the present invention.

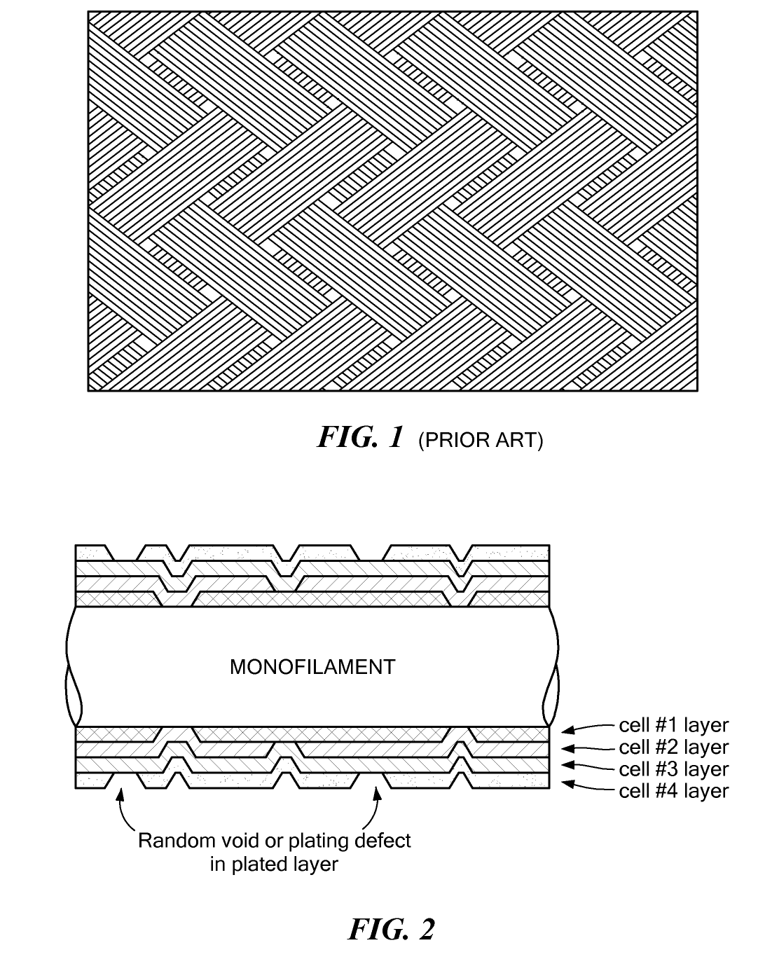

### DETAILED DESCRIPTION OF THE INVENTION

This application is a non-provisional application claiming priority from U.S. Provisional Application No. 61/505,339, filed Jul. 7, 2011, entitled “Electrical Shielding Material Composed of Metallized Aluminum Monofilaments,” the contents of which is incorporated by reference herein for all purposes.

### Starting Material.

The composition of the starting yarn bundle in terms of the diameter of the aluminum monofilaments and the total number of monofilaments in the bundle can be varied to suit the requirements of the end-use application. For example, one application might call for a yarn configuration of 14 monofilaments, each nominally 38 microns in diameter, whereas another might call for 10 monofilaments each nominally 50 microns in diameter. In one embodiment, the monofilaments are less than about 150 microns in diameter and the number of monofilaments in a yarn bundle is less than about 200. A bobbin of starting material will typically contain several thousand meters per kilogram of yarn.

A requirement of the starting material is that the twist imparted to the yarn bundle be less than about 3 turns/inch (120 turns/meter), generally no more than 0.500 turns/inch (20 turns/meter). The yarn bundle can even be completely untwisted but this configuration is difficult to transport through the process stations without one or more of the monofilaments becoming detached from the bundle and wrapping around the guide or electrical contact rollers.

The low-twist yarn construction, together with a low tension means of transport, allows the process chemistry to completely penetrate the yarn bundle and thereby insure the complete plating of the innermost monofilaments. The low-twist construction also allows the individual monofilaments to move with respect to each other as they are transported through the low tension metallization process. This not only contributes to plating uniformity but prevents the monofilaments from plating or adhering to each other, thereby ensuring that the flexibility of the starting yarn is preserved in its fully plated state.

Unlike stainless steel yarn, wherein the monofilaments in yarn form are produced in a wire drawing process, aluminum/aluminum alloy monofilaments such as the above are not produced in the form of multi-filament bundles, twisted or otherwise. Rather, they are commercially available only as discrete, ultra-fine wires that are individually drawn and wound up on plastic bobbins. Thus, the aluminum yarn is made by unwinding, marrying together, twisting, and taking-up the aluminum monofilaments without breaking them as they have very low break strength values, typically less than 40 grams.

### Metallization Process.

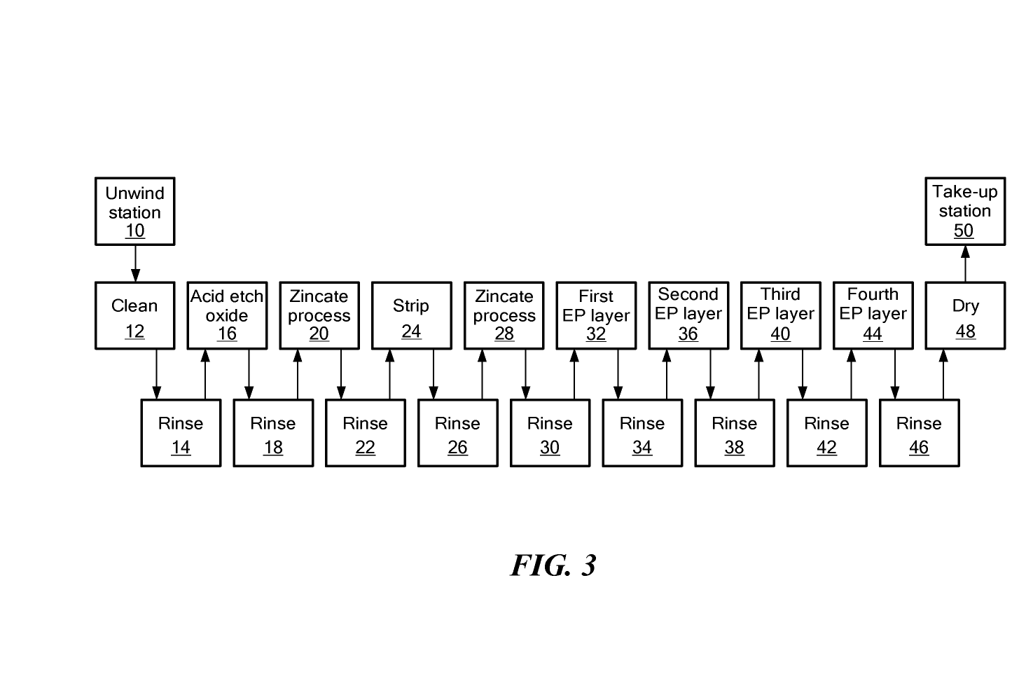

The prepared yarn is transported through successive stations to accomplish the metallization process which is illustrated schematically in FIG. 3. This continuous process consists of two distinct sections, a zincate process which is common to all yarn constructions in accordance with the various embodiments of the present invention described herein and an electroplating process that is variable in terms of the alternative metallizations that can be selected to meet different application requirements.

### Zincate Process.

The bobbins of starting material at station 10 are mounted on spindles which dispense the low-twist yarn into the process under control of a braking device that regulates the back tension on the yarn bundle. The yarn proceeds to station 12 where an ultrasonically agitated cleaning solution removes from the monofilament surfaces any oils or other organic contaminants that remain from the monofilament drawing process. There is a wide range of commercially available cleaning solutions that can be employed in this step which is followed by a series of de-ionized (DI) water rinse cells in station 14.

To remove the oxide layer formed on the aluminum monofilament surfaces, the yarn bundle is next immersed in an acid etching solution in station 16. There are several commercially available proprietary etching solutions that can be employed in this step which is followed by a series of DI rinse cells in station 18.

The yarn then enters the first zincate process station 20 wherein a conductive anchor or bonding layer of fine zincate crystals is formed on the surfaces of the aluminum monofilaments. There are a number of commercially available proprietary zincate chemistries that can be employed in this step which is followed by a series of DI rinse cells in station 22.

The yarn next advances to station 24 where an acid stripping solution is used to remove loosely adhered zinc particles and expose a clean aluminum surface for the second zincate step. After passing through a thorough rinse in station 26 the yarn is given a second zincating treatment in station 28 followed by a double rinse in station 30. This process can also be carried out in a single zincating step and there are other aluminum surface treatment methods available that are based on immersion tin.

### Electroplating Process.

Although the electroplating process is variable in terms of the range of metallized constructions that it can produce to meet different application requirements, the process sequence itself is common to all constructions. Emerging from the zincating process, the yarn enters a first layer electroplating station 32, then rinse station 34. The yarn is then transported to a second layer electroplating station 36, which is followed by rinse station 38. The yarn proceeds on to a third layer electroplating station 40, which is followed by rinse station 42. When a fourth layer is required, the yarn enters a fourth layer electroplating station 44, which is followed by rinse station 46, and then moves on to a drying station 48. After drying, the yarn is transported to a take-up station 50. Although all stations could be designated to deposit the same metal/metal alloy, greatest flexibility is achieved when each station is devoted to a different metal/metal alloy.

In conventional practice for nickel/tin-plated #36 or #34 AWG copper wire used in braided shielding, the tensile strength of the wire and its high conductivity allows the wire to be plated in long trough-like cells at high speed under high tension and high current. This practice cannot be used to electroplate aluminum yarn comprised of ultra fine (and therefore relatively low strength and low conductivity) aluminum monofilaments. Instead, the yarn must be advanced under low tension through the sequence of stations, each of which consists of a series of individual cells so that the plating current can be gradually increased to avoid burning out the delicate aluminum filaments.

As illustrated in FIG. 2, a beneficial aspect of this transport scheme is that it imparts to the deposit formed within each plating station a multilayer structure that minimizes the likelihood that voids or plating defects generated in one cell (layer) will be replicated in subsequent cells (layers) and thereby form a via or path that would allow corrosive fluid to migrate from the surfaces of the metallized monofilaments and attack the underlying aluminum.

The plating chemistry in each electroplating station is continuously circulated and vigorously agitated by virtue of a pumping system that discharges the solution into the plating tank through nozzles (so-called “spargers”) arrayed across the bottom of the tank.

The innermost filaments in the yarn bundle are plated by advancing the bundle through the process steps in a serpentine fashion such that the yarn bundle remains under low tension throughout the process. In addition, as the loose yarn is passed through, the monofilaments are spread out and allow the process chemistry to fully penetrate the yarn bundle. Advantageously, with this approach, the rinsing steps will effectively remove all traces of process chemistry before the yarn is dried and wound up. The speed of transport of the yarn through the process stations and the amount of time that the yarn remains at each station is variable depending upon the concentration of the bath solutions and the desired plating thicknesses to be applied.

From an application standpoint, there are four categories of combined corrosion resistance and electrical performance that the metallized aluminum yarn of this invention can satisfy with its various constructions.

### 1. Improved Corrosion Resistance.

This performance category requires sufficient corrosion resistance to pass at least 500 hours, with a goal of 1,000 hours, exposure to neutral salt spray/fog in a test chamber and an initial DC resistance of no more than 1 ohm/ft (3.25 ohms/m). Most applications other than shipboard fall into this basic performance category whose requirements can be met with a single layer of metallization about 3-4 microns thick. Nickel is advantageous for its superior corrosion resistance and relatively low cost but other electroplate-able metals/metal alloys such as tin, bronze, brass, chromium, the noble metals, a tin/lead alloy and a tin/silver alloy could be employed if other requirements such as solderability (for which nickel is not well-suited) are presented. Of course, precious metals such as platinum, gold, rhodium and silver also provide superior corrosion resistance but their extremely high cost has to be factored in when considering them for the metal thickness involved in this construction.

2. Improved Corrosion Resistance with Greater Electrical Conductivity.

This category calls for the same corrosion resistance as above but a DC resistance of less than 0.75 ohms/ft (2.4 ohms/m) in order to achieve a higher order of shielding effectiveness (which is inversely proportional to the impedance of the braided shield). Since the resistance of the overall yarn construction is dominated by the resistance of the underlying aluminum monofilaments, the goal of lower DC resistance calls for the addition of a layer of an electroplate-able metal with lower resistivity than aluminum. However, with the exception of copper, all of the candidate metals that meet this requirement are precious metals and thus, from a cost-based standpoint, copper is often the choice. Accordingly, the requirements for this construction can be addressed with a first electroplated layer of copper 2-3 microns thick and a second layer of nickel (or alternative metal/metal alloy per category 1 above) 3 microns thick. In this construction the copper layer is deposited from an alkaline copper solution or other non-acid copper formulations such as pyrophosphate copper or cyanide copper.

### 3. Optimal Corrosion Resistance.

In this category the metallized construction must provide the aluminum yarn with sufficient corrosion protection to pass at least 200 hours—with a goal of 336 hours—exposure to salt spray/fog infused with sulfur dioxide. In terms of electrical properties, DC resistance of no more than 1 ohm/ft (3.25 ohms/m) is satisfactory. To provide this enhanced level of corrosion resistance, the aluminum yarn is metallized with a three layer construction, the outer two layers of which are comprised of a noble metal/metal alloy and a less noble metal/metal alloy that combine to form a corrosion-retarding galvanic couple in the presence of an electrolytic fluid such as salt water or salt spray/fog containing sulfur dioxide. In this arrangement, the less noble metal/metal alloy is the outermost layer and, as the “sacrificial anode” in the couple, serves to retard the rate at which the more-noble underlying metal/metal alloy (cathode) deteriorates.

Although there are a number of metals/metal alloys that by themselves exhibit good resistance to salt water corrosion, there are certain considerations that limit the number of candidates that can practically be used to form the galvanic couple of this invention. A first consideration is that, unless the anode surface area is much smaller than that of the cathode, the rate of anode corrosion is controlled by the activity level of the cathode: slow rates of corrosion are achieved when “low activity” metals/metal alloys are used as the cathode layer. Unfortunately, the metals/metal alloys with the lowest activity levels, i.e., those considered “most cathodic” in the “Anodic Index”, are also extremely expensive, e.g., platinum, gold, and rhodium.

Anodic Index for Selected Plateable Metals

| Plateable metals | V | |
|---|---|---|
| Platinum | 0.00 | Most Cathodic |
| Gold | 0.00 | |
| Silver | −0.15 | |
| Nickel | −0.30 | |
| Copper | −0.35 | |
| Bronze (low tin) | −0.40 | |
| Bronze (high tin) | −0.45 | |
| Admiralty Brass | −0.45 | |
| Naval Brass | −0.45 | |
| Chromium | −0.60 | |
| Tin | −0.65 | |
| Lead | −0.70 | |
| Iron | −0.85 | |
| Zinc | −1.25 | Most Anodic |

Source: Handbook of Corrosion Engineering

A second consideration is that the two metals/metal alloys in the couple should not be too far apart on the Anodic Index: the further apart, the greater the rate of anode corrosion. For harsh environments such as saltwater exposure, corrosion experts recommend that the two metals should not be separated by more than 0.30 volts, preferably no more than 0.15 volts. A third consideration is that the metals/metal alloys can be readily electroplated; however, a number of the metals/metal alloys known for good salt water corrosion, e.g., titanium, hastelloy, and monel, cannot be electroplated at all while others such as Admiralty or Naval brass involve complex binary or terniary plating solutions that are difficult to control. A fourth consideration is that the European Union's RoHS directive restricts the use of certain metals that are otherwise attractive for their corrosion resistance: cadmium; lead; and hexavalent chromium.

For this construction it is assumed that the DC resistance of the un-plated aluminum yarn is at least adequate for the application so that the metals/metal alloys that comprise the plated layers can be chosen for their corrosion resistance alone. Accordingly, the first electroplated layer would be a nickel sulfamate deposit (or alternative metal/metal alloy per Category 1 above) about 2 microns thick. The choices for the next two layers depend on the metal/metal alloy selected as the outermost layer which is the anode layer for the corrosion-retarding galvanic couple. If nickel (anodic index 0.30) is selected as the outer layer, silver (anodic index 0.15) would be a reasonably-priced metal that could serve as the underlying cathode layer. In this case, then, the second electroplated layer would be a silver layer about 1-2 microns thick and the third electroplated layer would be nickel about 2-3 microns thick. As an example of an alternative construction with perhaps less robust corrosion-resistance but lower cost, the first electroplated layer could be nickel, (or alternative metal/metal alloy per Category 1 above) followed by a second electroplated layer of Naval brass, followed by a third electroplated layer of tin.

4. Optimal Corrosion Resistance with Greater Electrical Conductivity.

This category calls for the same corrosion resistance as immediately above but a DC resistance of less than 0.5 ohms/ft (1.625 ohms/m) in order to achieve a higher order of shielding effectiveness. Per above, these requirements can be addressed with a first electroplated layer of copper about 2-3 microns thick deposited from an alkaline copper solution or other non-acid copper formulations such as pyrophosphate copper or cyanide copper. The balance of the construction consists of a second layer of nickel (or alternative metal/metal alloy per Category 1 above) about 2 microns thick, a third electroplated layer of silver about 1-2 microns thick and a fourth electroplated layer of nickel (or alternative metal/metal alloy per Category 1 above) about 2-3 microns thick, with the last two layers forming a corrosion-retarding galvanic couple. As an example of an alternative construction for the galvanic couple, the third electroplated layer could be Naval brass and the fourth electroplated layer tin.

### Various Embodiments of the Present Invention

The following embodiments of the present invention illustrate how these performance requirements can be met with the various metallized constructions that the present invention provides.

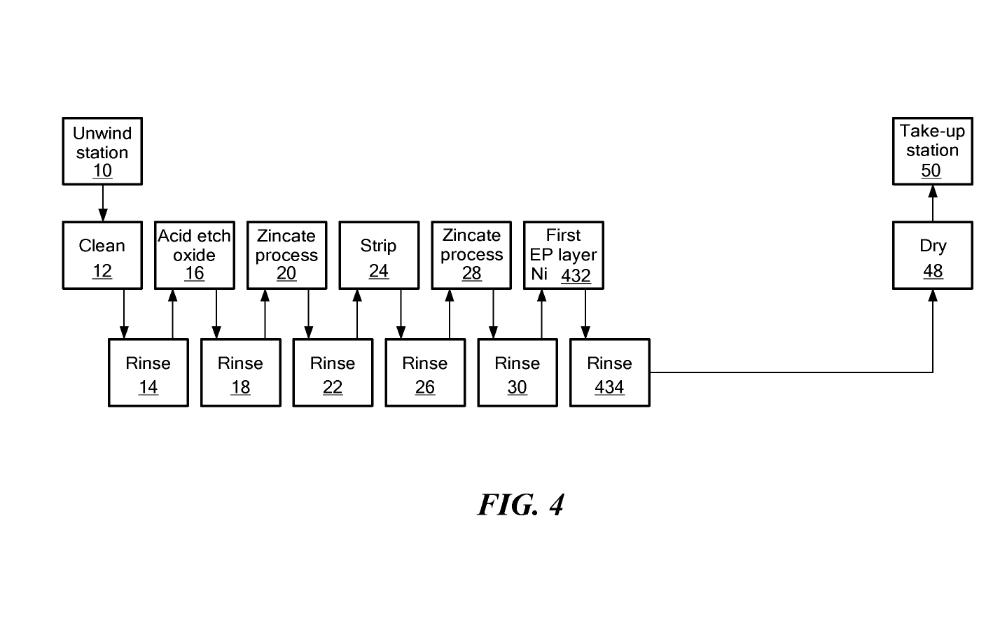

1. Improved Corrosion Resistance. FIG. 4 Illustrates a Process for this Performance Category.

Starting material. In this example, the starting yarn construction consists of 14 monofilaments of aluminum alloy 5052, each 38 microns in diameter, in a low twist format (0.375 turns/inch or 15 turns/meter). Although other aluminum alloys such as 6061 are suitable, alloy 5052 is advantageous for its superior salt water corrosion resistance.

Step 1. Clean and rinse. The starting yarn is conveyed through an ultrasonically agitated solution of MacDermid's Isoprep 160, a proprietary acid cleaning solution, (Station 12) followed by a double DI water rinse section (Station 14).

Step 2. Acid etch. The yarn is next conveyed through a proprietary acid etching solution, Metex AL Acid Etch, supplied by MacDermid, (Station 16) followed by a double DI water rinse section (Station 18).

Step 3. First zincate treatment and rinse. The yarn is next conveyed through a proprietary zincate solution, Metex 6811, supplied by MacDermid, (Station 20) followed by a double DI water rinse section (Station 22).

Step 4. Acid strip. The yarn is next conveyed through a proprietary solution, AL Prep 29 supplied by MacDermid (Station 24) to strip the first zincate layer. This is followed by a double DI water rinse section (Station 26).

Step 5. Second zincate treatment and rinse. The yarn is next conveyed through a second Metex 6811 solution (Station 28), followed by a double DI water rinse section (Station 30).

Step 6. First electroplated layer and rinse. The yarn is conveyed through a sequence of nickel plating baths (Station 432) which consist of a pre-formulated nickel sulfamate solution from MacDermid, Barrett SN. The nickel deposit in this case is about 3 microns thick. The yarn next enters a double DI water rinse section (Station 434) from which it is transported to the drying and take-up stations 48, 50.

QC Testing. Electrical resistance tests (ohms/unit length) are performed by wrapping the metallized yarn around two probes set 12 inches apart and measuring the resistance with an ohm meter; ten measurements are taken and averaged. The weight of the plated yarn is determined by weighing a precisely cut 3 foot length of yarn and averaging three measurements.

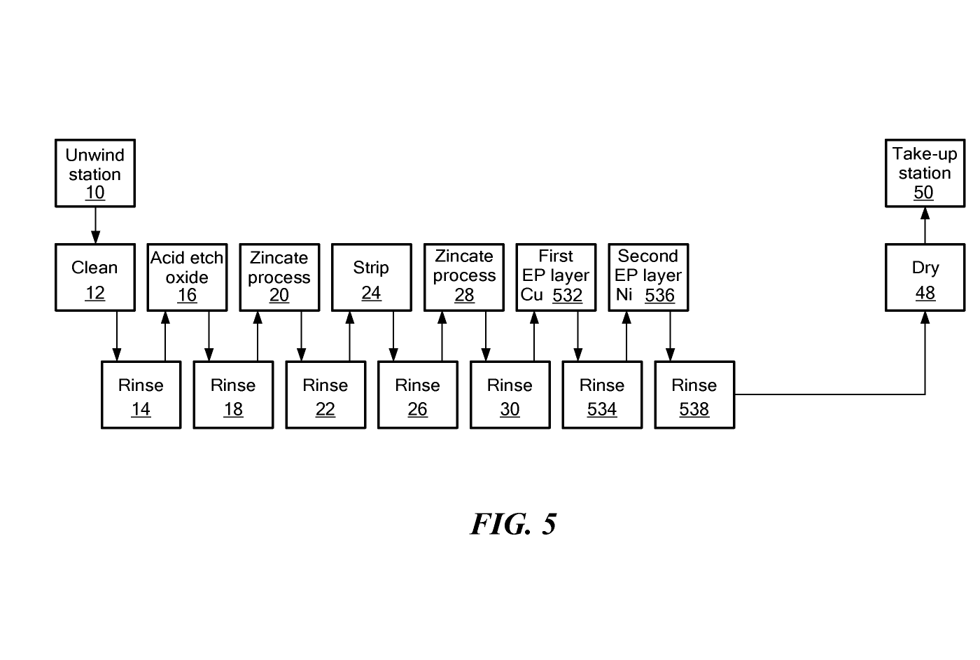

2. Improved corrosion resistance with greater electrical conductivity. FIG. 5 illustrates a process for this performance category.

Starting material. The starting yarn construction consists of 10 monofilaments of aluminum alloy 1000, each 50 microns in diameter, in a low twist format (0.375 turns/inch or 15 turns/meter).

Steps 1-5. Same as for Category 1.

Step 6. First electroplated layer and rinse. The yarn is conveyed through a sequence of copper plating baths (Station 532) which consist of a proprietary alkaline copper formulation supplied by Electrochemical Products, Inc., EBrite Ultra Cu. The copper deposit in this case is about 2-3 microns thick. This bath is followed by a double DI water rinse section (Station 534).

Step 7. Second electroplated layer and rinse. The yarn is conveyed through a sequence of nickel plating baths (Station 536) which consist of a pre-formulated nickel sulfamate solution from MacDermid, Barrett SN. The nickel deposit in this case is about 3 microns thick. The yarn next enters a double DI water rinse section (Station 538) from which it is transported to the drying and take-up stations 48, 50.

QC Testing. Same as above.

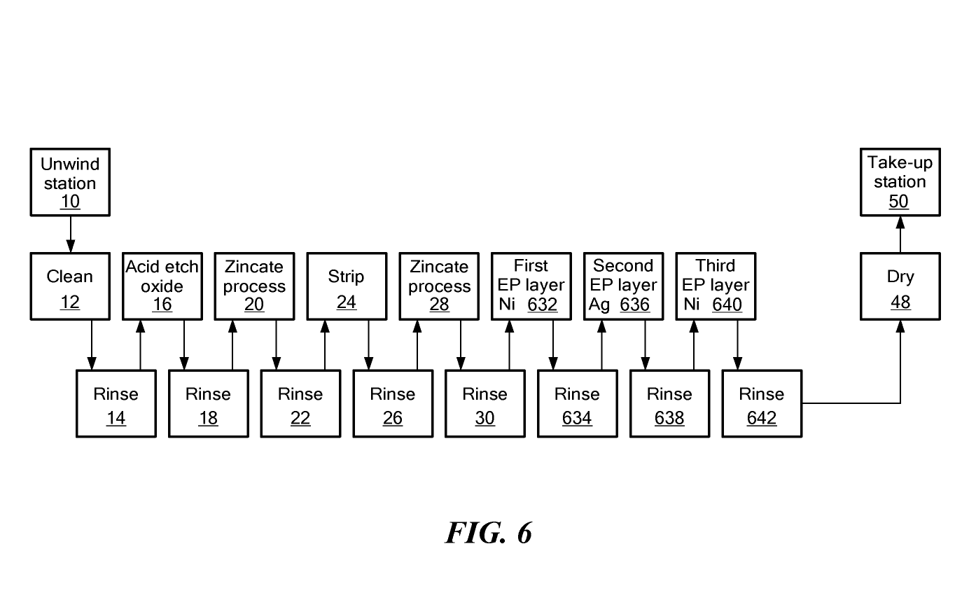

3. Optimal Corrosion Resistance. FIG. 6 Illustrates a Process for this Performance Category.

Starting material. In this example, the starting yarn construction consists of 14 monofilaments of aluminum alloy 5052, each 38 microns in diameter, in a low twist format (0.375 turns/inch or 15 turns/meter). Although other aluminum alloys such as 6061 are suitable, alloy 5052 is advantageous for its superior salt water corrosion resistance.

Steps 1-5. Same as for Category 1.

Step 6. First electroplated layer and rinse. The yarn is conveyed through a sequence of nickel plating baths (Station 632) which consist of a pre-formulated nickel sulfamate solution from MacDermid, Barrett SN. The nickel deposit in this case is about 2 microns thick. This bath is followed by a double DI water rinse section (Station 634).

Step 7. Second electroplated layer and rinse. The yarn is conveyed through a silver plating bath (Station 636) which contains a proprietary solution supplied by Technic, Cyless Silver II. The silver deposit in this case is about 1-2 microns thick. The rinse section (Station 638) consists of a mild (10%) sulfuric acid bath followed by a hot DI water rinse.

Step 8. Third electroplated layer and rinse. The yarn is conveyed through a sequence of nickel plating baths (Station 640) which consist of a pre-formulated nickel sulfamate solution from MacDermid, Barrett SN. The nickel deposit in this case is about 2-3 microns thick. This bath is followed by a double DI water rinse section (Station 642). The yarn is then transported to the drying and take-up stations 48, 50.

QC Testing. Same as above.

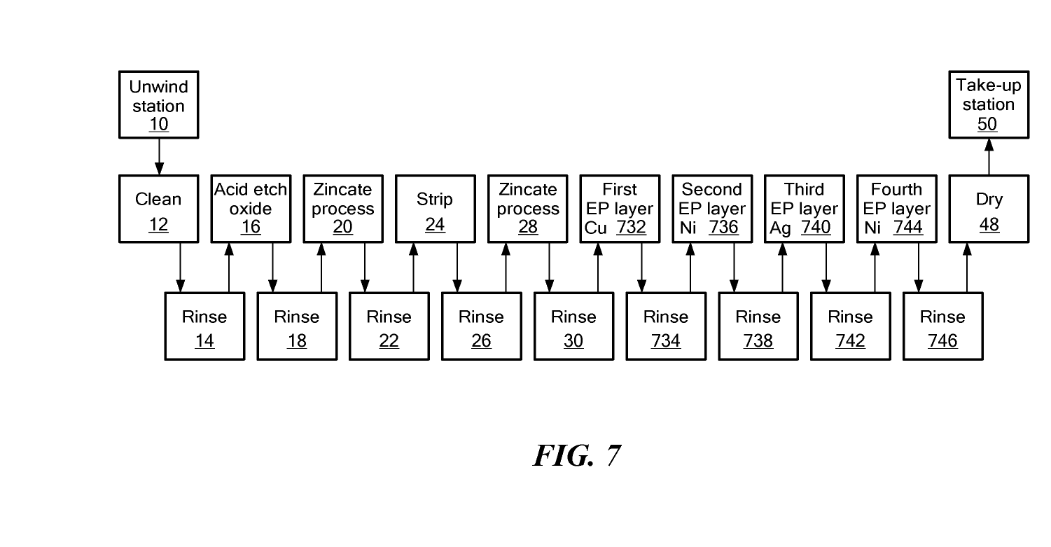

4. Optimal Corrosion Resistance with Greater Electrical Conductivity. FIG. 7 illustrates a Process for this Performance Category.

Starting material. In this example, the starting yarn construction consists of 10 monofilaments of aluminum alloy 1100, each 50 microns in diameter, in a low twist format (0.375 turns/inch or 15 turns/meter).

Steps 1-5. Same as Category 1.

Step 6. First electroplated layer and rinse. The yarn is conveyed through a sequence of copper plating baths (Station 732) which consist of a proprietary alkaline copper formulation supplied by Electrochemical Products, Inc., EBrite Ultra Cu. The copper deposit in this case is about 2-3 microns thick. This bath is followed by a double DI water rinse section (Station 734).

Step 7. Second electroplated layer and rinse. The yarn is conveyed through a sequence of nickel plating baths (Station 736) which consist of a pre-formulated nickel sulfamate solution from MacDermid, Barrett SN. The nickel deposit in this case is about 2 microns thick. This bath is followed by a double DI water rinse section (Station 738).

Step 8. Third electroplated layer and rinse. The yarn is conveyed through a silver plating bath (Station 740) which contains a proprietary solution of supplied by Technic, Cyless Silver II. The silver deposit in this case is about 1-2 microns thick. The rinse section (Station 742) consists of a mild (10%) sulfuric acid bath followed by a hot DI water rinse.

Step 9. Fourth electroplated layer and rinse. The yarn is conveyed through a sequence of nickel plating baths (Station 744) which consist of a pre-formulated nickel sulfamate solution from MacDermid, Barrett SN. The nickel deposit in this case is about 2-3 microns thick. This bath is followed by a double DI water rinse section (Station 746). The yarn is then transported to the drying and take-up stations 48, 50.

QC Testing. Same as above.

### EXAMPLES

### Example 1

In accordance with the embodiment for improved corrosion resistance, Category 1, a 500 foot length of yarn comprised of 14 aluminum alloy 5052 monofilaments, each 38 microns in diameter, was plated with a first layer of nickel about 3-4 microns thick. The metallized yarn had an electrical resistance of 0.95 ohms/ft (3.1 ohms/m) and a weight of 24 mg/ft (78 mg/m). The plated metal had good adhesion to the monofilaments and inspection of the yarn bundle under a microscope revealed that all of the monofilaments were completely and substantially uniformly coated with plated metal. The yarn was braided into a 0.500″ diameter tube which was then subjected to a 500 hour neutral salt spray/fog corrosion test. The braided tubing was removed from the test chamber after 1000 hours. Visual inspection determined that the underlying aluminum metal was not exposed and the resistance changed less than 20%. The 0.500″ diameter braided aluminum tubing weighed 1.8 g/ft compared to a weight of 22.3 g/ft for the same size tubing braided with #36 AWG copper/nickel wire, a weight reduction of 92%.

### Example 2

In accordance with the embodiment for improved corrosion resistance with greater electrical conductivity, Category 2, a 500 foot length of yarn comprised of 10 aluminum alloy 1000 monofilaments, each 50 microns in diameter, was plated with a first layer of copper about 2 microns thick and a second layer of nickel about 3 microns thick. The metallized yarn had an electrical resistance of 0.5 ohms/ft (1.63 ohms/m) and a weight of 39 mg/ft (27 mg/m). The plated metal had good adhesion to the monofilaments and inspection of the yarn bundle under a microscope revealed that all of the monofilaments were completely and substantially uniformly coated with plated metal. The yarn was braided into a 0.500″ diameter tube which was then subjected to a 500 hour neutral salt spray/fog corrosion test. The braided tubing was removed from the test chamber after 1000 hours. Visual inspection determined that the underlying aluminum metal was not exposed and the resistance changed less than 15%. The 0.500″ diameter braided aluminum tubing weighed 2.9 g/ft compared to a weight of 22.3 g/ft for the same size tubing braided with #36 AWG copper/nickel wire, a weight reduction of 87%.

### Example 3

In accordance with the embodiment for optimal corrosion resistance, Category 3, a 500 foot length of yarn comprised of 14 aluminum alloy 5052 monofilaments, each 38 microns in diameter, was plated with a first layer of nickel about 2 microns thick, followed by a second layer of silver about 1.5 microns thick, followed by a third layer of nickel about 3 microns thick. The metallized yarn had an electrical resistance of 0.95 ohms/ft (3.1 ohms/m) and a weight of 36 mg/ft (117 mg/m). The plated metal had good adhesion to the monofilaments and inspection of the yarn bundle under a microscope revealed that all of the monofilaments were completely and substantially uniformly coated with plated metal. The yarn was braided into a 0.500″ diameter tube which was then subjected to a 200 hour test involving salt spray/fog infused with sulfur dioxide. The braided tubing was removed from the test chamber after 400 hours. Visual inspection determined that the underlying aluminum metal was not exposed and the resistance changed less than 30%. The 0.500″ diameter braided aluminum tubing weighed 2.6 g/ft compared to a weight of 22.3 g/ft for the same size tubing braided with #36 AWG copper/nickel wire, a weight reduction of 88%.

### Example 4

In accordance with the embodiment for optimal corrosion resistance with greater electrical conductivity, Category 1, a 500 foot length of yarn comprised of 10 aluminum alloy 1000 monofilaments, each 50 microns in diameter, was plated with a first layer of copper about 2 microns thick, followed by a second layer of nickel about 2 microns thick, followed by a third layer of silver about 1.5 microns thick, followed by a fourth layer of nickel about 3 microns thick. The metallized yarn had an electrical resistance of 0.5 ohms/ft (1.63 ohms/m) and a weight of 51.2 mg/ft (166 mg/m). The plated metal had good adhesion to the monofilaments and inspection of the yarn bundle under a microscope revealed that all of the monofilaments were completely and substantially uniformly coated with plated metal. The yarn was braided into a 0.500″ diameter tube which was then subjected to the aforesaid 200 hour test. The braided tubing was removed from the test chamber after 400 hours. Visual inspection determined that the underlying aluminum metal was not exposed and the resistance changed less than 25%. The 0.500″ diameter braided aluminum tubing weighed 3.8 g/ft compared to a weight of 22.3 g/ft for the same size tubing braided with #36 AWG copper/nickel wire, a weight reduction of 83%.

The metallized aluminum yarn of this invention may also be advantageously used in braided shielding applications that are incorporated into coaxial cables. Furthermore, the highly conductive metallized yarn materials of this invention can be advantageously used in applications other than braided shielding. The metallized monofilaments or yarn can, for example, be woven into flexible, lightweight fabrics suitable for protecting sensitive electronic equipment. They can be cut or chopped into staple fiber lengths and mixed with plastic or rubber molding compounds to incorporate RFI/EMI shielding into electronic equipment enclosures or gasket materials. The metallized monofilaments can also be incorporated into various shapes and forms in non-woven fabrics and materials to suit particular purposes.

The yarn can also be further twisted in single or multiple plies to provide a highly flexible, lightweight conductor suitable for low voltage applications such as battery-powered heating elements for cold weather clothing or, passively, an antenna incorporated into apparel.

Accordingly, the invention is not to be limited to what has been particularly shown and described and is to include the full spirit and scope of the appended claims.

1. A conductive multi-fiber comprising:
a plurality of monofilaments, each monofilament comprising:
an aluminum/aluminum alloy monofilament; and
a first electroplated layer of a first metal or first metal alloy completely and substantially uniformly electroplated on each aluminum/aluminum alloy monofilament.

2. The conductive multi-fiber of claim 1, wherein the first electroplated layer comprises a metal or metal alloy having corrosion resistant properties.

3. The conductive multi-fiber of claim 1, wherein the first metal or first metal alloy is chosen from the group consisting of nickel, tin, bronze, brass, chromium, the noble metals, a tin/lead alloy and a tin/silver alloy.

4. The conductive multi-fiber of claim 2, wherein the first electroplated layer has sufficient corrosion resistance to prevent visual exposure of the underlying monofilament after exposure to a neutral salt spray/fog for at least 500 hours.

5. The conductive multi-fiber of claim 2, wherein the first electroplated layer has sufficient corrosion resistance to prevent visual exposure of the underlying monofilament after exposure to a neutral salt spray/fog for at least 1000 hours.

6. The conductive multi-fiber of claim 1, wherein:
the plurality of monofilaments has a twist of no more than 3 turns/inch; and
the first electroplated layer is produced by low tension transport of the plurality of monofilaments through electroplating process stations wherein each station comprises multiple plating cells.

7. The conductive multi-fiber of claim 1, further comprising:
a second electroplated layer of a second metal or second metal alloy completely and substantially uniformly electroplated on the first electroplated layer of each monofilament.

8. The conductive multi-fiber of claim 7, wherein:
the first metal or first metal alloy is a metal or metal alloy with a resistivity lower than that of aluminum; and
the second metal or second metal alloy is a metal or metal alloy having corrosion resistant properties.

9. The conductive multi-fiber of claim 8, wherein the first metal or first metal alloy is chosen from the group consisting of copper and the precious metals.

10. The conductive multi-fiber of claim 8, wherein the second metal or second metal alloy is chosen from the group consisting of nickel, tin, bronze, brass, chromium, the noble metals, a tin/lead alloy and a tin/silver alloy.

11. The conductive multi-fiber of claim 8, wherein the second electroplated layer has sufficient corrosion resistance to prevent visual exposure of the underlying monofilament after exposure to a neutral salt spray/fog for at least 500 hours.

12. The conductive multi-fiber of claim 8, wherein the second electroplated layer has sufficient corrosion resistance to prevent visual exposure of the underlying monofilament after exposure to a neutral salt spray/fog for at least 1000 hours.

13. The conductive multi-fiber of claim 7, wherein:
the plurality of monofilaments has a twist of no more than 3 turns/inch; and
the first and second electroplated layers are produced by low tension transport of the plurality of monofilaments through electroplating process stations wherein each station comprises multiple plating cells.

14. The conductive multi-fiber of claim 7, further comprising:
a third electroplated layer of a third metal or third metal alloy completely and substantially uniformly electroplated on the second electroplated layer of each monofilament.

15. The conductive multi-fiber of claim 14, wherein:
the first metal or first metal alloy is a metal or metal alloy having corrosion resistant properties; and
the second metal or second metal alloy is a more noble metal or metal alloy than the third metal or third metal alloy; and
the third metal or third metal alloy is a metal or metal alloy having corrosion resistant properties.

16. The conductive multi-fiber of claim 15, wherein the first metal or first metal alloy is chosen from the group consisting of nickel, tin, bronze, brass, chromium, the noble metals, a tin/lead alloy and a tin/silver alloy.

17. The conductive multi-fiber of claim 15, wherein the third metal or third metal alloy is chosen from the group consisting of nickel, tin, bronze, brass, chromium, the noble metals, a tin/lead alloy and a tin/silver alloy.

18. The conductive multi-fiber of claim 15, wherein the second metal or second metal alloy is separated from the third metal or third metal alloy by no more than about 0.30 volts on the Anodic Index.

19. The conductive multi-fiber of claim 15, wherein the second metal or second metal alloy is separated from the third metal or third metal alloy by no more than about 0.15 volts on the Anodic Index.

20. The conductive multi-fiber of claim 15, wherein a combined corrosion resistance of the three electroplated layers is sufficient to prevent visual exposure of the underlying monofilament after exposure to a salt spray/fog infused with sulfur dioxide for at least 200 hours.

21. The conductive multi-fiber of claim 15, wherein a combined corrosion resistance of the three electroplated layers is sufficient to prevent visual exposure of the underlying monofilament after exposure to a salt spray/fog infused with sulfur dioxide for at least 336 hours.

22. The conductive multi-fiber of claim 14 wherein:
the plurality of monofilaments has a twist of no more than 3 turns/inch; and
the first, second, and third electroplated layers are produced by low tension transport of the plurality of monofilaments through electroplating process stations wherein each station comprises multiple plating cells.

23. The conductive multi-fiber of claim 14, further comprising:
a fourth electroplated layer of a fourth metal or fourth metal alloy completely and substantially uniformly electroplated on the third electroplated layer of each monofilament.

24. The conductive multi-fiber of claim 23, wherein:
the first metal or first metal alloy is a metal or metal alloy with a resistivity lower than that of aluminum;
the second metal or second metal alloy is a metal or metal alloy having corrosion resistant properties; and
the third metal or third metal alloy is a more noble metal or metal alloy than the fourth metal or fourth metal alloy; and
the fourth metal or fourth metal alloy is a metal or metal alloy having corrosion resistant properties.

25. The conductive multi-fiber of claim 24, wherein the first metal or first metal alloy is chosen from the group consisting of copper and the precious metals.

26. The conductive multi-fiber of claim 24, wherein the second metal or second metal alloy and the fourth metal or fourth metal alloy are chosen from the group consisting of nickel, tin, bronze, brass, chromium, the noble metals, a tin/lead alloy and a tin/silver alloy.

27. The conductive multi-fiber of claim 24, wherein the third metal or third metal alloy is separated from the fourth metal or fourth metal alloy by no more than about 0.30 volts on the Anodic Index.

28. The conductive multi-fiber of claim 24, wherein third metal or third metal alloy is separated from the fourth metal or fourth metal alloy by no more than about 0.15 volts on the Anodic Index.

29. The conductive multi-fiber of claim 24, wherein a combined corrosion resistance of the four electroplated layers is sufficient to prevent visual exposure of the underlying monofilament after exposure to a salt spray/fog infused with sulfur dioxide for at least 200 hours.

30. The conductive multi-fiber of claim 24, wherein a combined corrosion resistance of the four electroplated layers is sufficient to prevent visual exposure of the underlying monofilament after exposure to a salt spray/fog infused with sulfur dioxide for at least 336 hours.

31. The conductive multi-fiber of claim 23, wherein:
the plurality of monofilaments has a twist of no more than 3 turns/inch; and
the first, second, third, and fourth electroplated layers are produced by low tension transport of the plurality of monofilaments through electroplating process stations wherein each station comprises multiple plating cells.

32. A braided or woven RFI/EMI cable shield in the form of a tubular sleeve comprised of the conductive multi-fiber of any of claim 1, 7, 14 or 23.

33. A coaxial cable incorporating a braided RFI/EMI shield comprised of the conductive multi-fiber of any of claim 1, 7, 14 or 23.

34. A woven fabric incorporating the conductive multi-fiber of any of claim 1, 7, 14 or 23.

35. A non-woven fabric incorporating the conductive multi-fiber of any of claim 1, 7, 14 or 23.

36. A staple fiber cut or chopped from the conductive multi-fiber of any of claim 1, 7, 14 or 23.

37. A composite conductive multi-fiber consisting of at least two single-ply yarns of the conductive multi-fiber of any of claim 1, 7, 14 or 23 plied together.
